(19) United States
(12) Patent Application Publication
(10) Pub. No.: US 2016/0322607 A1
(43) Pub. Date: Nov. 3, 2016

(54) LIGHT-EMITTING DEVICE

(71) Applicant: PANASONIC INTELLECTUAL PROPERTY MANAGEMENT CO. LTD., Osaka (JP)

(72) Inventors: Yoshitaka NAKAMURA, Osaka (JP); Yasuhisa INADA, Osaka (JP); Akira HASHIYA, Osaka (JP); Taku HIRASAWA, Kyoto (JP)

(73) Assignee: PANASONIC INTELLECTUAL PROPERTY MANAGEMENT CO. LTD., Osaka (JP)

(21) Appl. No.: 15/104,366

(22) PCT Filed: Nov. 14, 2014
(86) PCT No.: PCT/JP2014/005725

§ 371 Date: Jun. 14, 2016

(30) Foreign Application Priority Data
Dec. 27, 2013 (JP) 2013-270883

(51) Int. Cl. H01L 51/52; H01L 51/56; H01L 51/50

(52) U.S. Cl. CPC H01L 51/5275; H01L 51/5203; H01L 51/5012; H01L 51/56

(57) ABSTRACT

An illuminator includes: a light-emitting element and a light-extraction layer which transmits light occurring from the light-emitting element. The light-emitting element includes a first electrode layer on the light-extraction layer side, the first electrode layer having a light transmitting property; a second electrode layer on the opposite side from the light-extraction layer; an emission layer between the first and the second electrode layers; and a feed portion disposed close to the first electrode layer, the second electrode layer, and the emission layer to apply a voltage between the first electrode layer and the second electrode layer. The light-extraction layer has a structure in which a low-refractive index layer having a relatively low refractive index and a high-refractive index layer having a higher refractive index than does the low-refractive index layer are stacked, an interface between the low-refractive index layer and the high-refractive index layer representing bump-dent features.

### TECHNICAL FIELD

The present application relates to an illuminator.

### BACKGROUND

In recent years, illuminators are being developed in which a light-emitting element such as an organic electro-luminescence device (hereinafter referred to as an “organic EL device”) is used. Organic EL devices are characterized by being self-light-emitting type devices, having emission characteristics with a relatively high efficiency, being capable of emission in various color tones, and so on. Therefore, their application to light-emitting elements in display devices (e.g., flat panel displays) and light sources (e.g., backlights or illuminations for liquid crystal display devices) is considered as promising.

As examples of organic EL devices, those are known in which a hole injection layer, a hole transport layer, an emission layer, an electron transport layer, and a metal electrode (cathode) are stacked in this order on a transparent electrode (anode) that is formed on the surface of a transparent substrate. By applying a voltage between the anode and the cathode, light can be generated from the emission layer. The generated light, is transmitted through the transparent electrode and the transparent substrate to be extracted to the exterior.

In an organic EL panel in which such an organic EL device is used, the distance from a feed portion, from which a voltage is to be applied between the electrodes, differs depending on the planar position within the organic EL panel. Therefore, different amounts of voltage drop result depending on the internal resistance of the anode or cathode. This causes a problem in that the voltage to be applied to the light-emitting element and the size of the current to flow become distributed, resulting in emission unevenness.

A technique to solve this problem may be, for example, a technique which is disclosed in Patent Document 1. In Patent Document 1, auxiliary electrodes are deployed in the form of a grating over a transparent electrode of an organic EL panel, thereby restraining a voltage drop in the organic EL panel, and suppressing emission unevenness within the panel plane.

### CITATION LIST

### Patent Literature

[Patent Document 1] Japanese Laid-Open Patent Publication No. 2012-69450

### SUMMARY OF INVENTION

### Technical Problem

However, the aforementioned conventional technique separately requires auxiliary electrodes, thus resulting in a problem of complicated construction.

An embodiment of the present application provides an illuminator which is capable of suppressing emission unevenness without using auxiliary electrodes.

### Solution to Problem

In order to solve the above problem, an illuminator according to one implementation of the present invention is an illuminator comprising: a light-emitting element; and a light-extraction layer which transmits light occurring from the light-emitting element, the light-emitting element including a first electrode layer on the light-extraction layer side, the first electrode layer having a light transmitting property, a second electrode layer on an opposite side from the light-extraction layer, an emission layer between the first and second electrode layers, and a feed portion disposed close to the first electrode layer, the second electrode layer, and the emission layer to apply a voltage between the first electrode layer and the second electrode layer, wherein, the light-extraction layer has a structure in which a low-refractive index layer having a relatively low refractive index and a high-refractive index layer having a higher refractive index than does the low-refractive index layer are stacked, an interface between the low-refractive index layer and the high-refractive index layer representing bump-dent features; the light-extraction layer includes a first region and a second region which is more distant from the feed portion than is the first region; and the bump-dent features are adapted so that the second region has a higher light extraction efficiency than does the first region.

### Advantageous Effects of Invention

With the illuminator according to one implementation of the present invention, emission unevenness can be suppressed without using auxiliary electrodes.

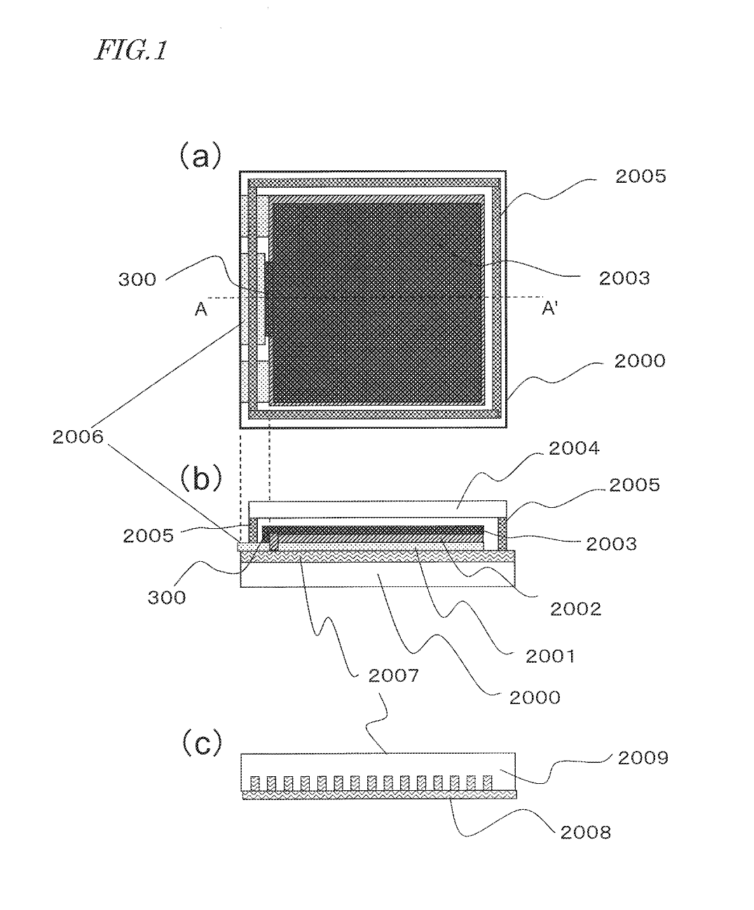

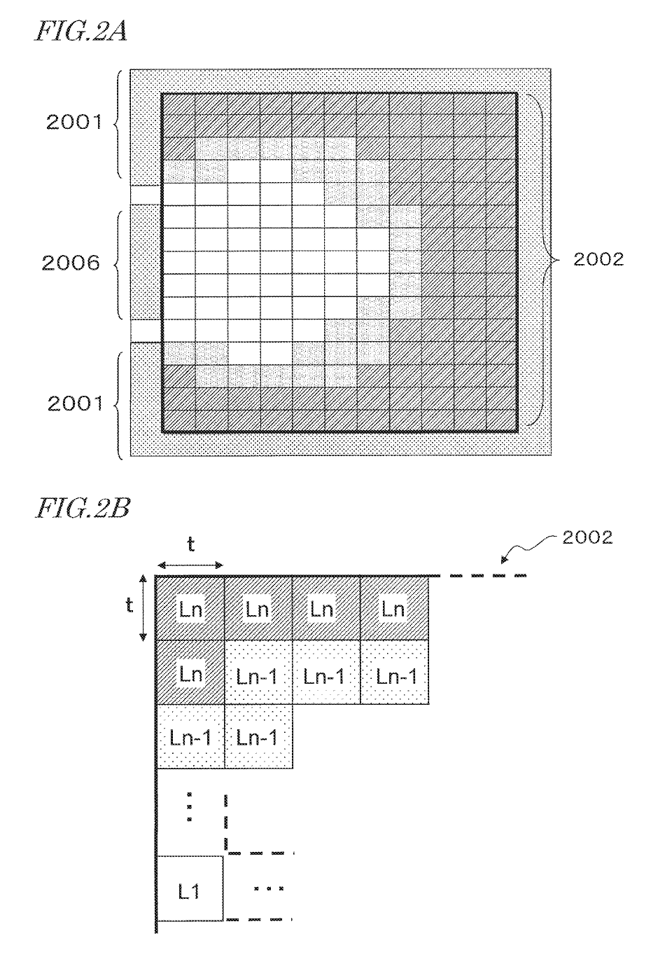

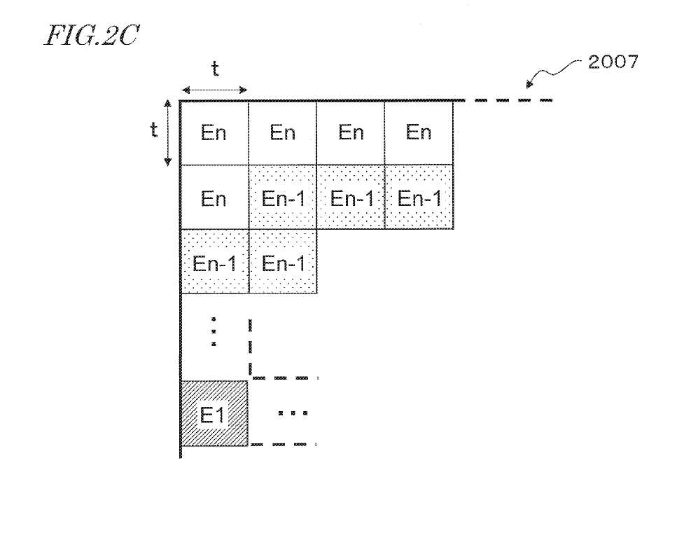

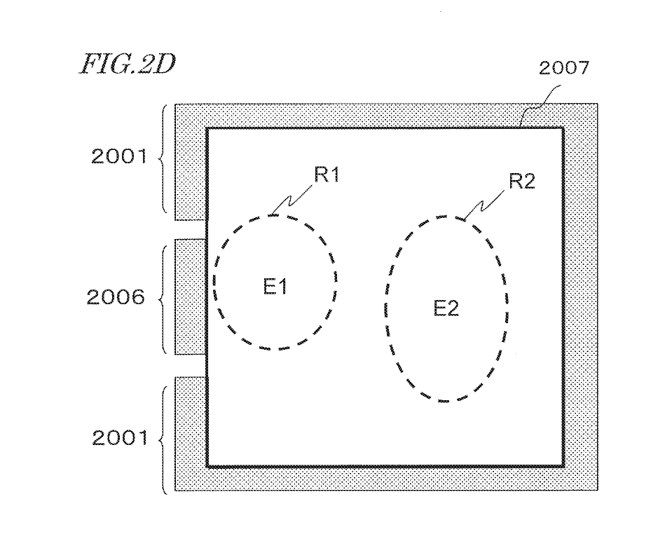

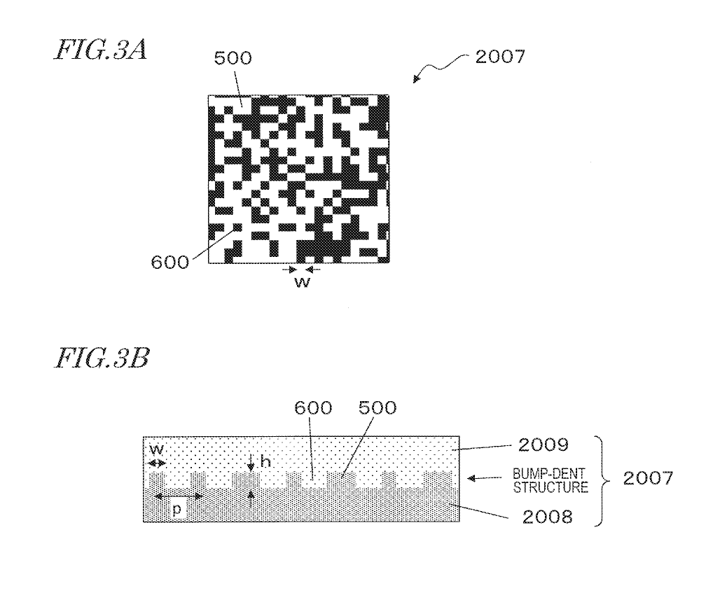

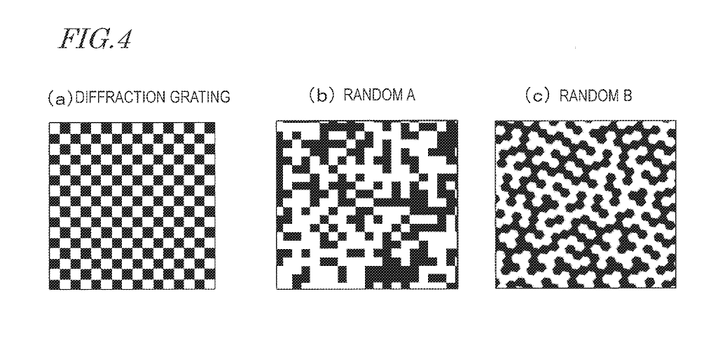

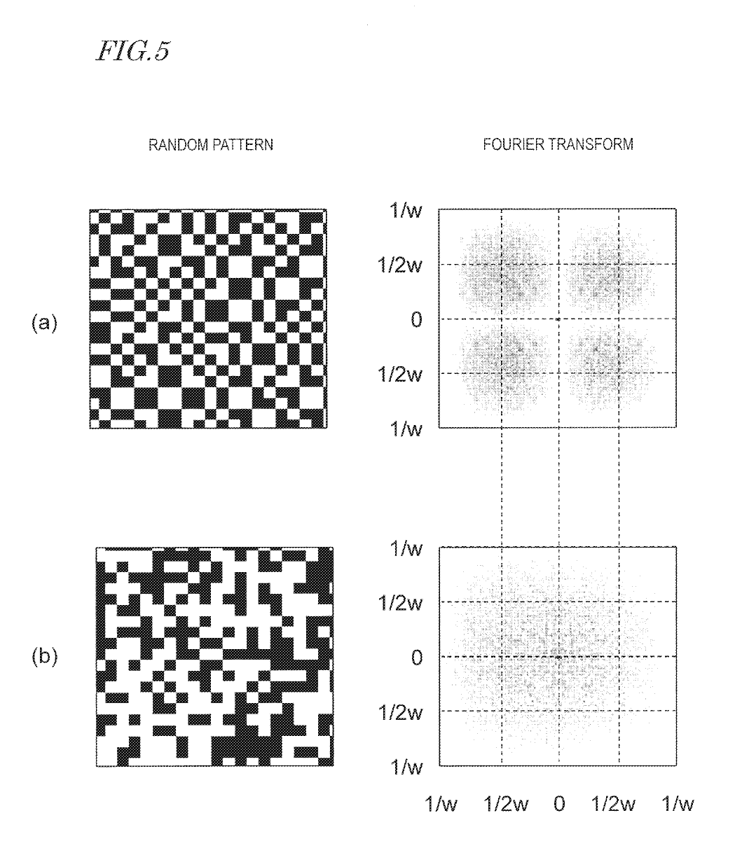

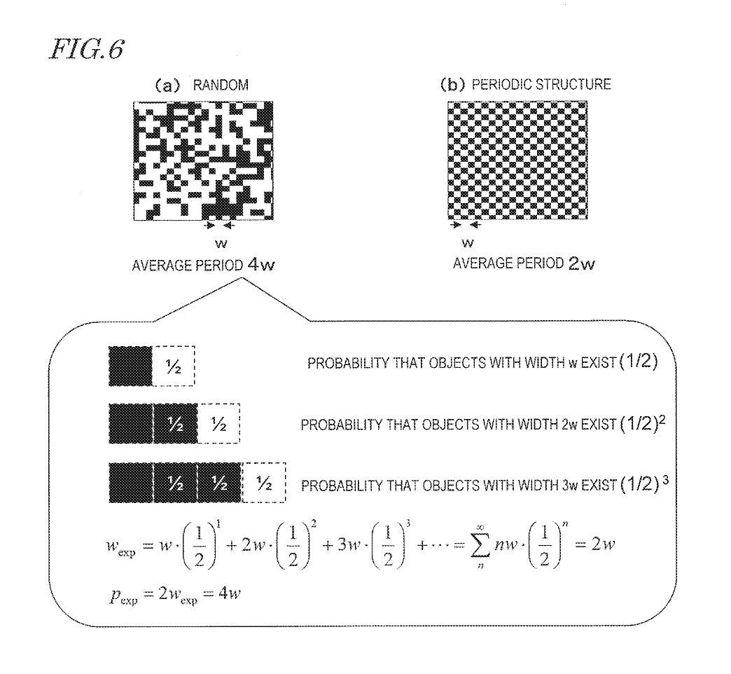

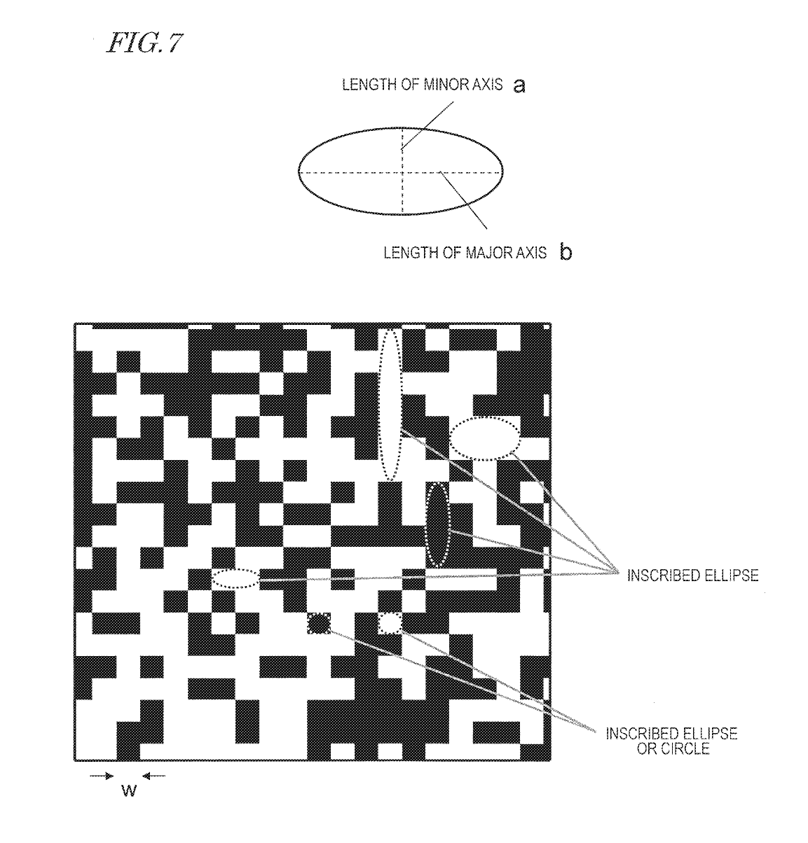

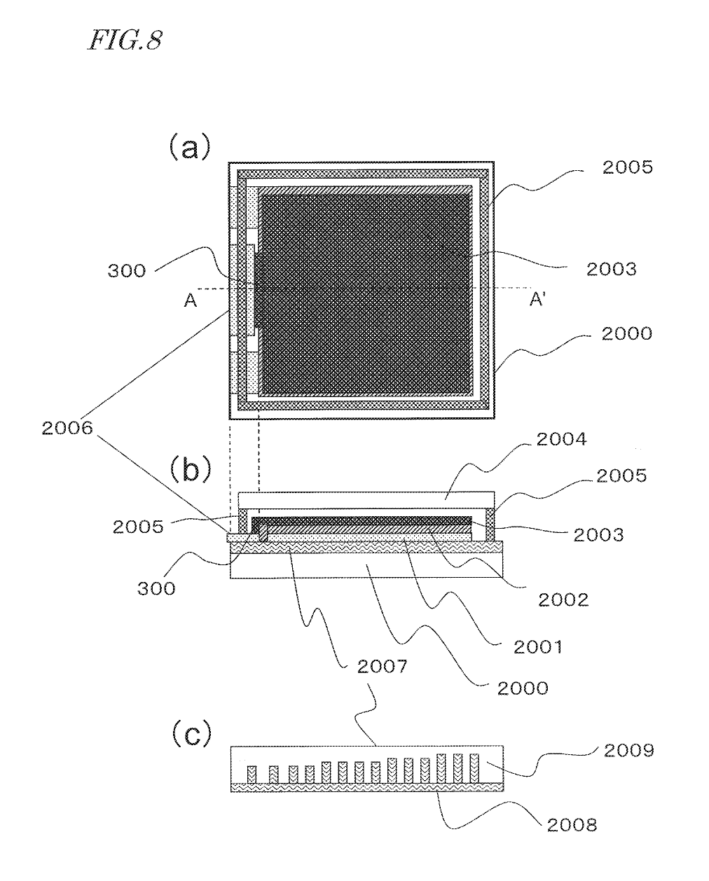

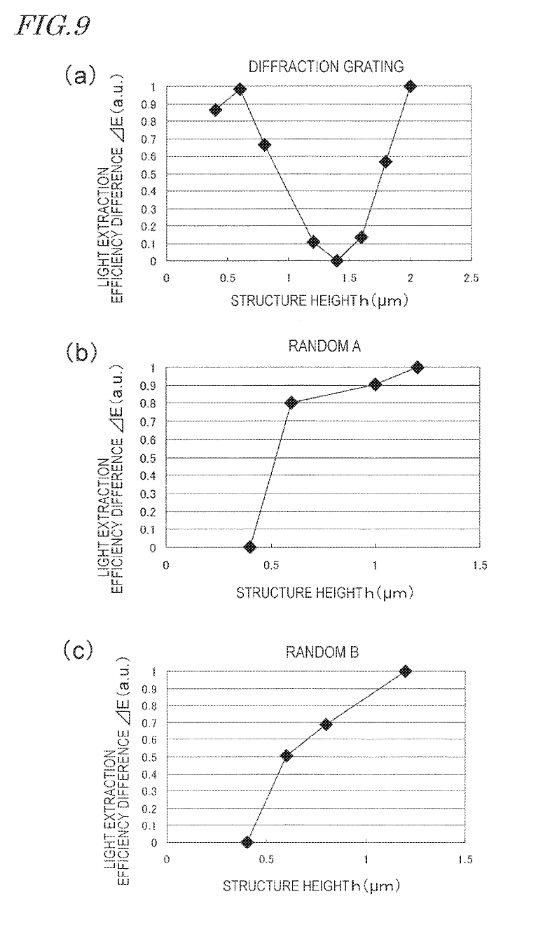

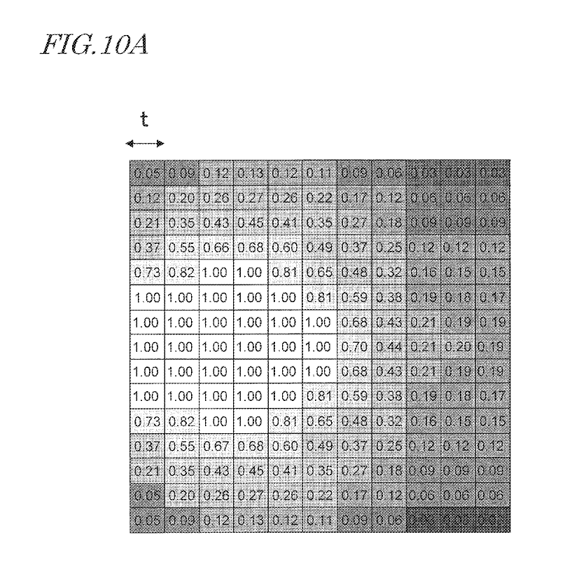

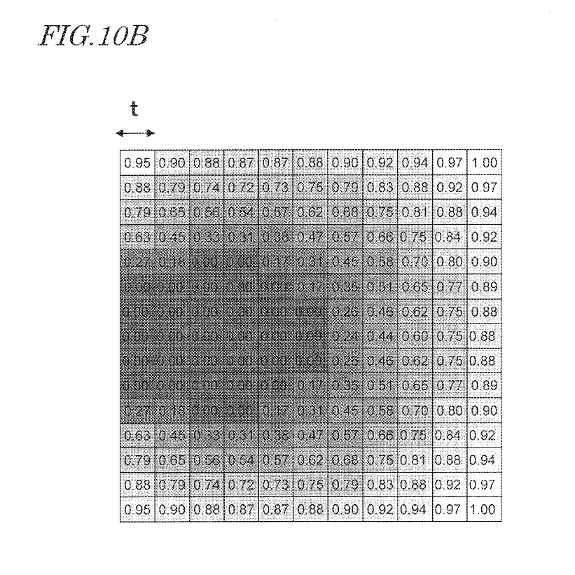

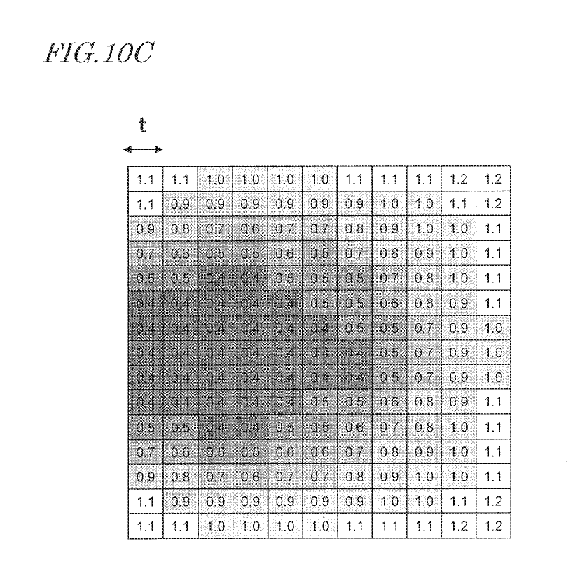

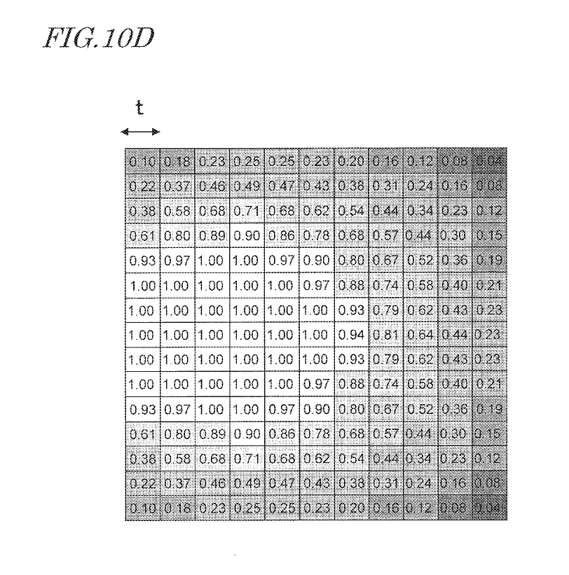

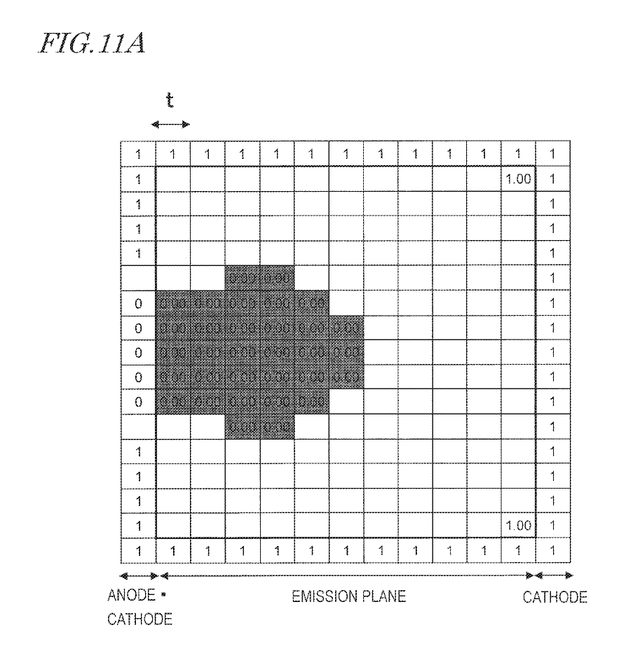

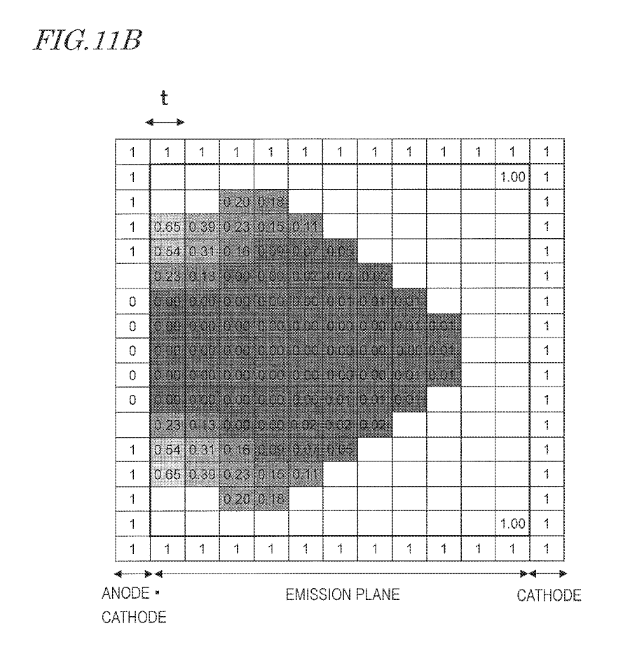

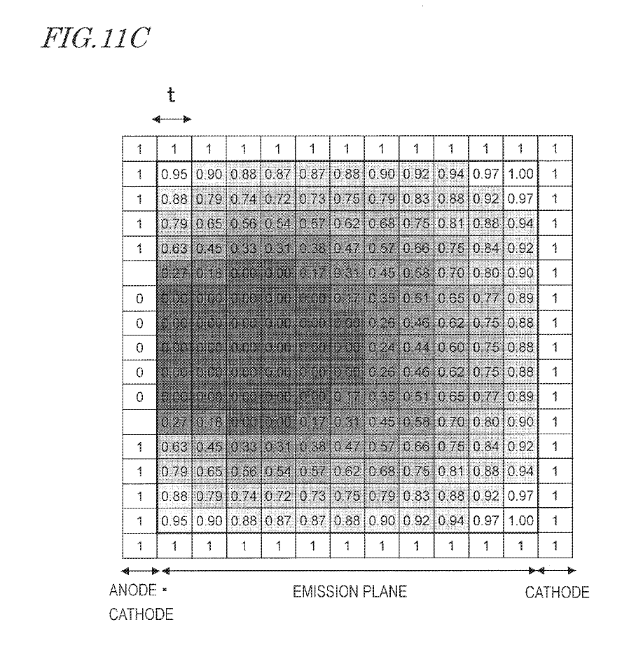

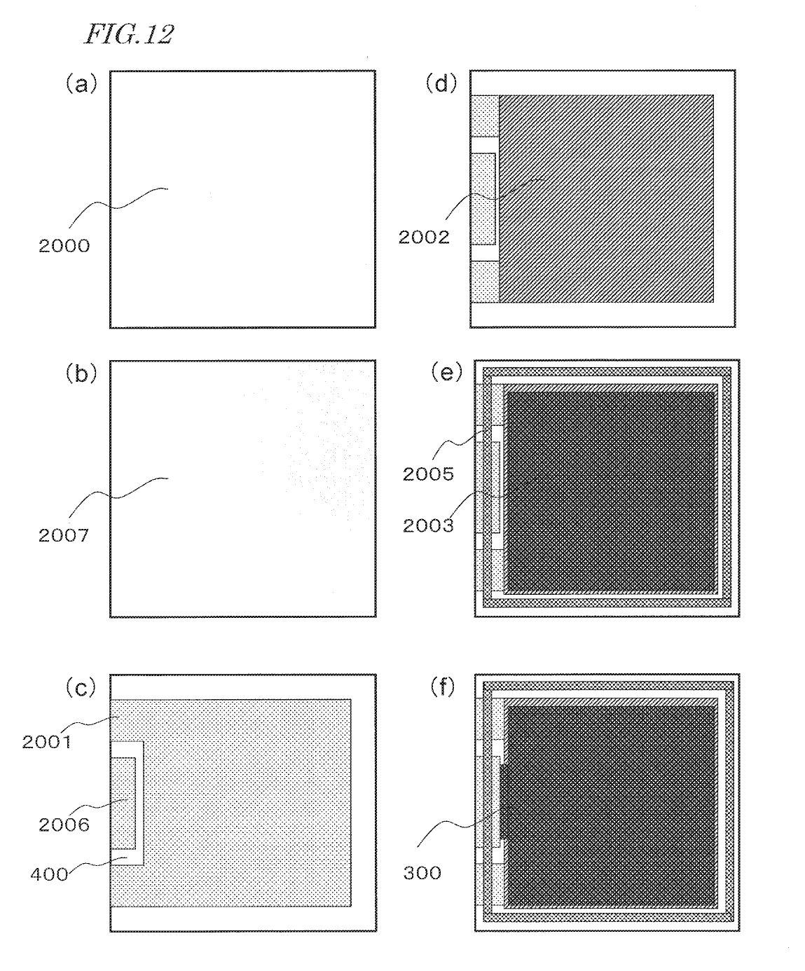

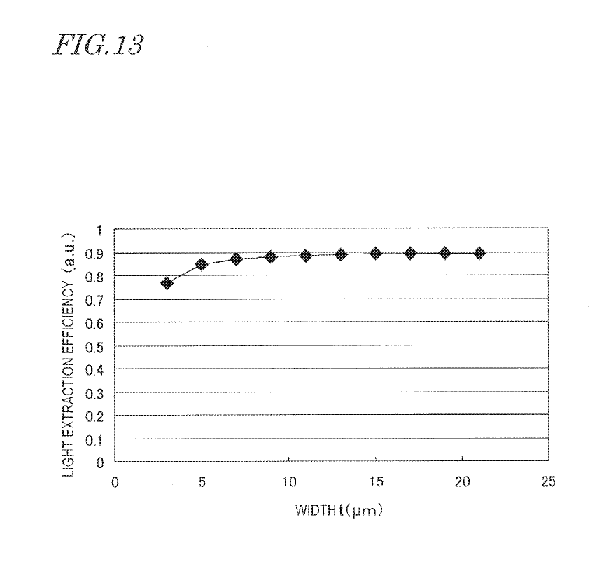

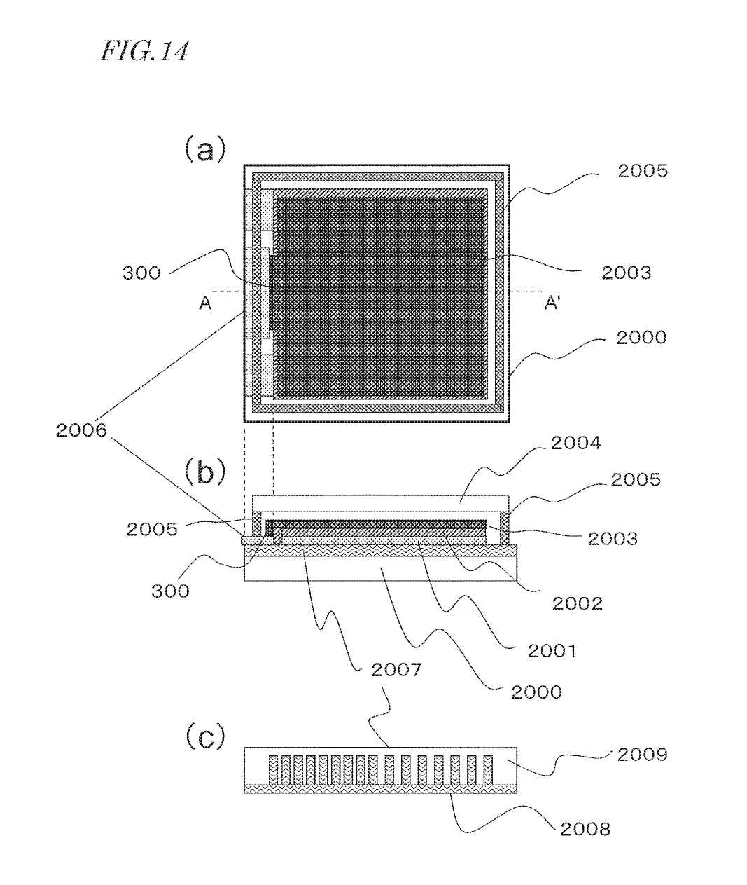

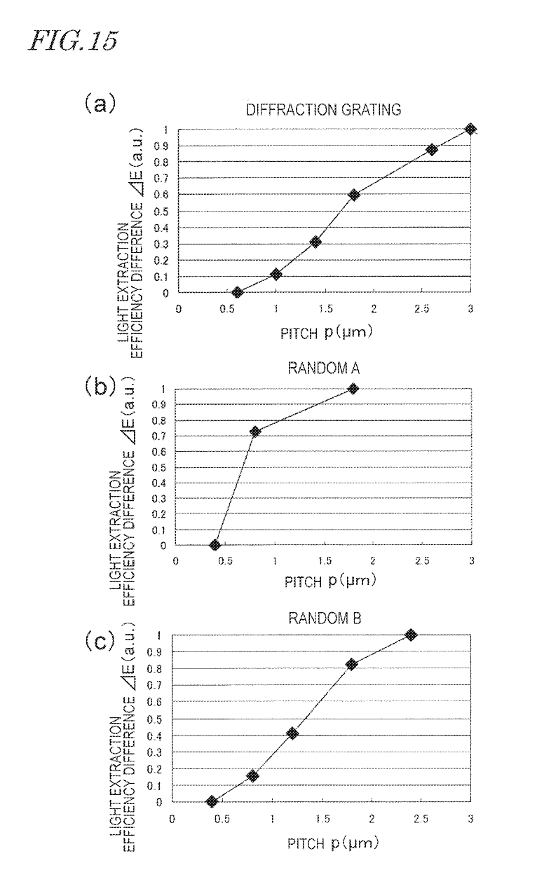

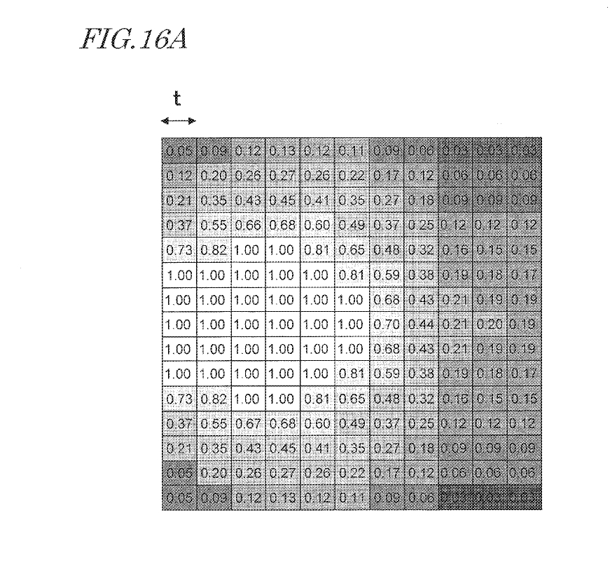

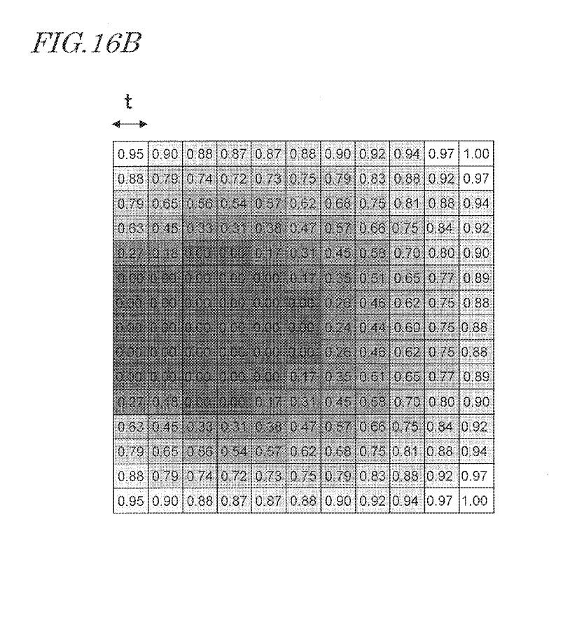

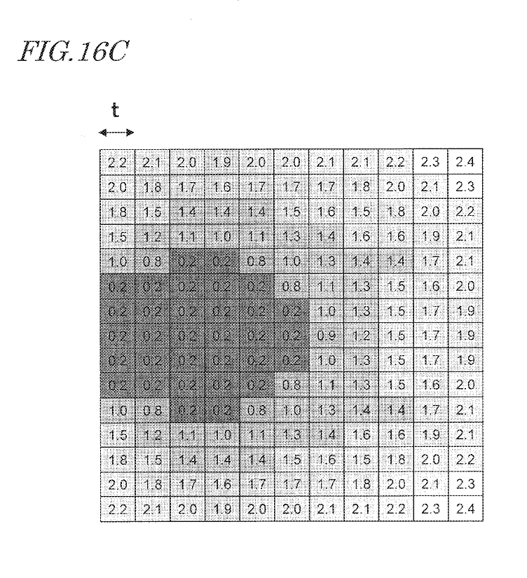

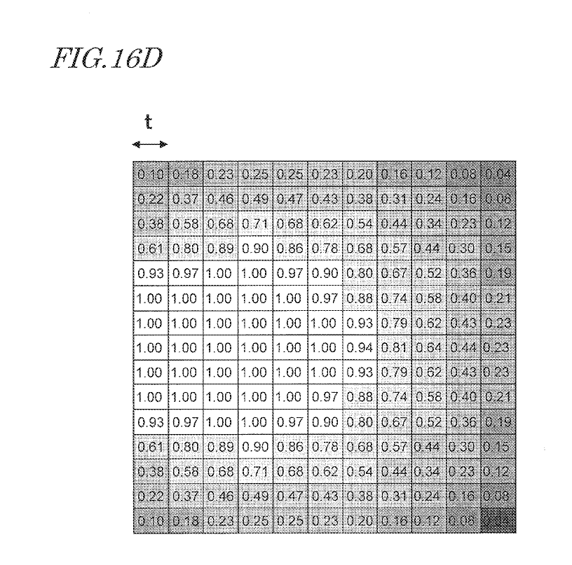

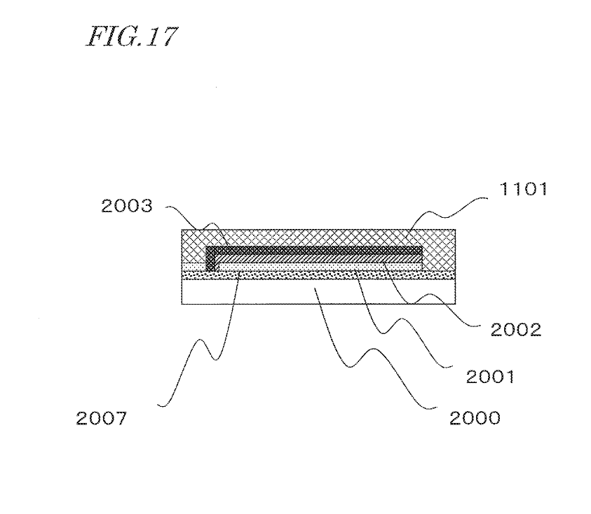

### BRIEF DESCRIPTION OF DRAWINGS

[FIG. 1] A diagram showing an example of a conventional organic EL panel.

[FIG. 2A] A diagram showing an exemplary simulation result concerning emission unevenness.

[FIG. 2B] A diagram showing an exemplary luminance distribution on the emission plane.

[FIG. 2C] A diagram showing an exemplary distribution of light extraction efficiency of a light-extraction layer 2007, corresponding to the luminance distribution shown in FIG. 2B.

[FIG. 2D] A diagram for explaining a light extraction efficiency distribution.

[FIG. 3A] plan view showing an exemplary bump-dent structure.

[FIG. 3B] A cross-sectional view showing an exemplary bump-dent structure.

[FIG. 4](a) is a diagram showing an example of a diffraction grating; (b) is a diagram showing an exemplary bump-dent structure with reduced randomness; and (c) is a diagram showing another exemplary bump-dent structure with reduced randomness.

[FIG. 5] A diagram showing amplitude of spatial frequency components when applying a Fourier transform to patterns of dents and bumps.

[FIG. 6] A diagram for explaining the period of a bump-dent, structure.

[FIG. 7] Another diagram for explaining the period of a bump-dent structure.

[FIG. 8] A diagram showing the construction of an organic EL panel according to illustrative Embodiment 1.

[FIG. 9] A diagram for explaining a relationship between light extraction efficiency and structure height, where (a) shows results for the structure shown in FIG. 4(a); (b) shows results for the structure shown in FIG. 4(b) ; and (c) shows results for the structure shown in FIG. 4(c).

[FIG. 10A] A diagram showing an exemplary luminance distribution on the emission plane according to Embodiment 1.

[FIG. 10B] A diagram showing an exemplary distribution of light extraction efficiency difference ΔE according to Embodiment 1.

[FIG. 10C] A diagram showing an exemplary height distribution of dents and bumps according to Embodiment 1.

[FIG. 10D] A diagram showing an exemplary luminance distribution in the case where a light-extraction layer is provided according to Embodiment 1.

[FIG. 11A] A first diagram showing a midway state of calculation leading up to the distribution shown in FIG. 10B.

[FIG. 11B] A second diagram showing a midway state of calculation leading up to the distribution shown in FIG. 10B.

[FIG. 11C] A diagram showing completion of the distribution calculation shown in FIG. 10B.

[FIG. 12](a) to (f) are diagrams illustrating an exemplary production method for an organic EL panel.

[FIG. 13] A diagram showing dependence of light extraction efficiency on width t.

[FIG. 14] A structural diagram of an organic EL panel according to Embodiment 2.

[FIG. 15] A diagram showing a relationship between light extraction efficiency and pitch, where (a) shows results for the structure shown in FIG. 4(a); (b) shows results for the structure shown in FIG. 4(b); and (c) shows results for the structure shown in FIG. 4(c).

[FIG. 16A] A diagram showing an exemplary luminance distribution on the emission plane according to Embodiment 2.

[FIG. 16B] A diagram showing an exemplary distribution of light extraction efficiency difference ΔE according to Embodiment 2.

[FIG. 16C] A diagram showing an exemplary pitch distribution of dents and bumps according to Embodiment 2.

[FIG. 16D] A diagram showing an exemplary luminance distribution in the case where a light-extraction layer is provided according to Embodiment 2.

[FIG. 17] A cross-sectional view showing the structure of an organic EL panel according to another embodiment.

### DESCRIPTION OF EMBODIMENTS

The present disclosure encompasses illuminators according to Items below.

[Item 1]

An illuminator comprising: a light-emitting element; and a light-extraction layer which transmits light occurring from the light-emitting element, the light-emitting element including a first electrode layer on the light-extraction layer side, the first electrode layer having a light transmitting property, a second electrode layer on an opposite side from the light-extraction layer, an emission layer between the first and second electrode layers, and a feed portion connected to at least one of the first electrode layer and the second electrode layer to apply a voltage between the first electrode layer and the second electrode layer, wherein, the light-extraction layer has a structure in which a low-refractive index layer having a relatively low refractive index and a high-refractive index layer having a higher refractive index than does the low-refractive index layer are stacked, an interface between the low-refractive index layer and the high-refractive index layer representing bump-dent features; the light-extraction layer includes a first region and a second region which is more distant from the feed portion than is the first region; and the bump-dent features are adapted so that the second region has a higher light extraction efficiency than does the first region.

[Item 2]

The illuminator of Item 1, wherein the light-extraction layer is divided into a plurality of regions including the first and second regions, the bump-dent features being adapted so that the light extraction efficiency in each region increases as there is a smaller amount of transmitted light through a portion of the first electrode layer opposing that region.

[Item 3]

The illuminator of Item 1 or 2, wherein an average value of heights of the bump-dent features in the second region is greater than an average value of heights of the bump-dent features in the first region.

[Item 4]

The illuminator of Item 3, wherein the light-extraction layer is divided into a plurality of regions including the first and second regions such that the bump-dent features in each region has a constant height, and the height of the bump-dent features in each region is determined in accordance with an amount of transmitted light through a portion of the first electrode layer opposing that region.

[Item 5]

The illuminator of Item 4, wherein the plurality of regions include two regions differing in terms of the height of the hump-dent features, the difference in terms of the height between the two regions being 100 nm or more.

[Item 6]

The illuminator of any of items 1, 2, 4 and 5, wherein an average value of periods of the bump-dent features in the second region is longer than an average value of periods of the bump-dent features in the first region.

[Item 7]

The illuminator of Item 6, wherein the light-extraction layer is divided into a plurality of regions including the first and second regions, and an average value of periods of the bump-dent features in each region is determined in accordance with an amount of transmitted light through a portion of the first electrode layer opposing that region.

[Item 8]

The illuminator of Item 6 or 7, wherein the plurality of regions include two regions differing in terms of an average value of the periods of the bump-dent features, the difference in terms of the average value of the periods being 100 nm or more.

[Item 9]

The illuminator of Item 4 or 7, wherein each of the plurality of regions has an identical area, and has a width of 10 μm or more along a direction which is parallel to the light-extraction layer.

[item 10]

The illuminator of any of Items 1 to 9, wherein the bump-dent features are shaped so that a plurality of dents and a plurality of bumps are arrayed in a pattern with two-dimensional randomness.

[Item 11]

The illuminator of Item 10, wherein, given a minimum value w of length of a shorter side of an ellipse inscribed in each of the plurality of dents and the plurality of bumps, among spatial frequency components of the pattern of the bump-dent features, any component smaller than 1/(2 w) is suppressed as compared to a case where the plurality of dents and the plurality of bumps are randomly arrayed.

[Item 12]

The illuminator of Item 11, wherein the bump-dent features are adapted so that no predetermined number of dents or bumps or more are successively present along one direction.

[Item 13]

The illuminator of item 12, wherein, when cut along a plane which is parallel to the light-extraction layer, each of the plurality of dents and the plurality of bumps has a rectangular cross-sectional shape, and the bump-dent features are adapted so that no three or more dents or bumps are successively present along arrangement directions.

[Item 14]

The illuminator of Item 12, wherein, when cut along a plane which is parallel to the light-extraction layer, each of the plurality of dents and the plurality of bumps has a hexagonal cross-sectional shape, and the bump-dent features are adapted so that no four or more dents or bumps are successively present along the arrangement directions.

[Item 15]

The illuminator of any of claims Items 11 to 14, wherein, given an average wavelength λ of light occurring from the emission layer, the minimum value of length of the shorter side of the ellipse inscribed in each of the plurality of dents and the plurality of bumps is 0.73λ or more.

[Item 16]

The illuminator of any of Items 1 to 9, wherein the bump-dent features are structured so that a plurality of dents and a plurality of bumps are in a periodic two-dimensional array.

[Item 17]

The illuminator of any of Items 1 to 16, wherein, given an average wavelength λ of light occurring from the emission layer, the low-refractive index layer has a thickness of (½)λ or more.

[Item 18]

The illuminator of any of Items 1 to 17, wherein, the light-extraction layer further includes a light-transmitting substrate; the low-refractive index layer is formed on a face of the light transmitting substrate that is closer to the light-emitting element; and the high-refractive index layer is formed between the low-refractive index layer and the first electrode layer. [Item 19]

The illuminator of any of Items 1 to 18, wherein the light-emitting element is an organic EL device.

Prior to describing embodiments of the present disclosure, a finding that served as a basis of the present disclosure will be described first. In the following description, an illuminator which emits light from the entire emission plane may be referred to as a “plane emission device”. Plane emission devices encompass not only individual light-emitting panels (e.g., organic EL panels), but also apparatuses having a large-sized emission plane which is composed of a plurality of panels being coupled together.

As mentioned earlier, conventional plane emission devices may have the problem of emission unevenness. As used herein, “emission unevenness” refers to a state where, between positions of largest luminance on the emission plane and positions of smallest luminance, there exists a certain luminance ratio or greater.

FIG. 1 is a diagram showing an example of a plane emission device (organic EL panel) in which an organic EL device is used. FIG. 1(a) is a plan view showing the structure of this organic EL panel, and FIG. 1(b) is a cross-sectional view taken along line A-A′ in FIG. 1(a). As shown in FIG. 1(b), this organic EL panel is structured so that a transparent substrate 2000 made of a transparent material such as glass, a light-extraction layer 2007, a transparent electrode 2001, an organic layer 2002, and a metal electrode 2003 are stacked in this order. The organic layer 2002 is structured so that an electron injection layer, an electron transport layer, an emission layer, a hole transport layer, and a hole injection layer, which are not shown, are stacked in this order. In order to cause light emission in the organic layer 2002, voltage is applied between the transparent electrode 2001 and the metal electrode 2003,

An organic material which is used for organic EL may deteriorate in an environment with oxygen or moisture. Therefore, in the construction shown in FIG. 1, another glass substrate 2004 is fixed with a sealant 2005, thereby protecting the organic EL device. In order to apply voltage between the transparent electrode 2001 and the metal electrode 2003, a feed portion 2006 which passes under the sealant 2005 to be connected to the metal electrode 2003 is provided in the periphery of the substrate. The metal electrode 2003 and the feed portion 2006 are connected via a connecting portion 300. Note that, contrary to this example, the feed portion 2006 may in some cases be connected to the transparent electrode 2001. Moreover, the feed portion 2006 may be in positions other than the position shown in the figure. In either case, the feed portion 2006 is connected to at least one of the transparent electrode 2001 and the metal electrode 2003, thereby functioning as a voltage input terminal via which to apply voltage therebetween.

In order to suppress the total reflection of light caused by a refractive index difference between the transparent substrate 2000 and the transparent electrode 2001, this illuminator includes a light-extraction layer 2007 between the transparent substrate 2000 and the transparent electrode 2001. As shown in FIG. 1(c), the light-extraction layer 2007 includes resin 2008 and resin 2009, the resin 2008 being buried in the resin 2009. The interface between the resin 2008 and the resin 2009 represents bump-dent features, thus allowing a portion of light which strikes at an incident angle exceeding the critical angle to be effectively extracted to the exterior. The refractive index of the resin 2008 is smaller than the refractive index of the resin 2009. Therefore, in the following description, the layer which is made of the resin 2008 may be referred to as the “low-refractive index layer 2008”, and the layer made of the resin 2009 may be referred to as the “high-refractive index layer 2009”.

In such an organic EL panel based on an organic EL device, distance from the feed portion 2006 (i.e., a voltage input terminal of the metal electrode 2003 or the transparent electrode 2001) varies depending on the planar position within the organic EL panel. Therefore, the amount of voltage drop caused by a resistance component of the anode or cathode also varies depending on the planar position within the organic EL panel. This results in a problem in that the voltage to be applied to the emission layer and the current to flow may have a magnitude distribution, which causes emission unevenness.

FIG. 2A is a diagram showing an exemplary simulation result concerning emission unevenness, as carried out by the inventors. When the transparent electrode 2001 and the feed portion 2006 are disposed as shown in FIG. 2A, emission unevenness occurs depending on the distance from the feed portion 2006. More specifically, when the emission plane of the organic layer (emission layer) 2002 is divided into an imaginary plurality of square regions with an invariable width t, as illustrated in FIG. 2B, there is varying luminance from region to region. In the example shown in FIG. 2B, given a highest luminance L1 and a lowest luminance Ln (where n is a natural number of 2 or more), there is a luminance distribution in n steps, from L1, L2, . . . Ln-1 to Ln.

A conceivable cause of emission unevenness is that, in a plane emission device having a certain area, distance from the feed portion 2006 varies depending on the position within the emission plane of the plane emission device, so that the value of the voltage drop caused by a resistance component of the anode or cathode also varies depending on the position.

Against this problem, Patent Document 1 takes an approach where a correction voltage is applied to the central portion of the plane emission device by using auxiliary electrodes, thereby suppressing the voltage drop and reducing emission unevenness of the plane emission device. However, this approach additionally requires an auxiliary power source, thus complicating the construction. Moreover, the auxiliary electrodes may be visually perceivable depending on how thick they are, thus leading to a problem of degrading the appearance in an application to a display or illumination.

The inventors have located the aforementioned problems of the conventional techniques, and vigorously looked for a simple construction that solves the aforementioned problems without having to add any component elements such as auxiliary electrodes. As a result, the inventors have concluded that emission unevenness can be reduced by adapting the bump-dent structure of the light-extraction layer 2007.

Specifically, in order to reduce emission unevenness of an illuminator, bump-dent features may be adapted so that the light extraction efficiency in regions of low luminance of the emission plane is improved. For example, emission unevenness can be improved by ensuring that the light extraction efficiency in at least the regions of lowest luminance is relatively high and that the light extraction efficiency in at least the regions of highest luminance is relatively low. Herein, “light extraction efficiency” means a rate of the intensity of transmitted light to the intensity of incident light.

FIG. 2C is a diagram showing an exemplary distribution of light extraction efficiency of the light-extraction layer 2007 that results in the luminance distribution shown in FIG. 2B. In the example shown in FIG. 2C, the light extraction efficiency of each region is adjusted in accordance with the emission amount so that the light extraction efficiency in the regions of lowest luminance to has a maximum value En and that the light extraction efficiency in any region of the light-extraction layer 2007 that opposes a region of highest luminance L1 has a minimum value E1. More strictly speaking, the light-extraction layer 2007 has its bump-dent features adapted so that the light extraction efficiency of each region decreases as there is a greater amount of transmitted light through a portion of the transparent electrode layer 2001 opposing that region.

Such adjustment is not needed for all regions; unevenness in luminance can be improved so long as the light extraction efficiency differs between regions of particularly low luminance and regions of particularly high luminance. For example, as shown in FIG. 2D, the bump-dent features of the light-extraction layer 2007 may be adapted so that the light extraction efficiency E2 of a region R2 which is relatively far from the feed portion 2006 is greater than the light extraction efficiency E1 of a first region R1 which is relatively close to the feed portion 2006. Such construction allows to compensate for a decrease in the emission amount due to a voltage drop that is caused by the electrical resistance of the transparent electrode 2001 or the metal electrode 2003.

As a specific means for achieving the light extraction efficiency adjustment, the inventors have found that shape parameters of the bump-dent structure of the light-extraction layer 2007 may be adjusted in order to vary the light extraction efficiency. As specific shape parameters, the bump-dent structure pattern of the light-extraction layer 2007 and the height and pitch (period) of the dents and bumps have been studied. The results of these studies are described below.

First, with reference to FIG. 3A and FIG. 3B, the fundamental principle behind the bump-dent structure of the light-extraction layer 2007 will be described.

FIG. 3A is a plan view schematically showing an exemplary bump-dent structure of the light extraction layer 2007. In FIG. 3A, black and white regions respectively represent portions (bumps) where the high-refractive index layer 2009 is formed relatively thick and portions (dents) where the high-refractive index layer 2009 is formed relatively thin. This bump-dent structure is a random two-dimensional array of two kinds of square-shaped unit structures (with a level difference h) each having a side length (width) w. In the following description, the level difference h may be referred to as the “height” of the bump-dent structure, and each unit structure may be referred to as a “block”. By providing such a bump-dent structure, light occurring from the emission layer 2002 can be effectively extracted through diffraction.

FIG. 3B is a cross-sectional view schematically showing a portion of the bump-dent structure. The lateral direction in FIG. 3B coincides with the lateral direction in FIG. 3A. With respect to the lateral direction in FIG. 3B, the minimum length of a bump 600 or a dent 500 is defined as a width w, and the length between two adjoining bumps (or dents) is defined as a pitch p.

The structure shown in FIG. 3A and FIG. 3B is only exemplary, to which the bump-dent structure pattern is not limited. For example, a diffraction grating having a periodic pattern of dents and bumps as shown in FIG. 4(a) may be used. Moreover, as in the structure shown in FIGS. 4(b) and (a), instead of arraying the dents and bumps in a completely random manner, a structure with reduced randomness so that no unit structures of the same kind successively appear a predetermined number of times or more along the arrangement directions may be adopted. FIG. 4(b) shows a random pattern which is adjusted so that, when cut along a plane that is parallel to the light-extraction layer 2007, each of the plurality of dents and the plurality of bumps reveals a rectangular cross-sectional shape, and that no three or more dents or bumps are successively present along the arrangement directions. FIG. 4(c) shows a random pattern which is adjusted so that, when cut along a plane that is parallel to the light-extraction layer 2007, each of the plurality of dents and the plurality of bumps reveals a hexagonal cross-sectional shape, and that no our or more dents or bumps are successively present along the arrangement directions. As used herein, the “arrangement directions” refer to the lateral direction and the vertical direction in the example shown in FIG. 4(b), and the three directions that are perpendicular to the sides of a hexagon in the example shown in FIG. 4(c).

In structures with reduced randomness as shown in FIGS. 4(b) and (c), the efficiency of light extraction can be enhanced over a completely random structure as shown in FIG. 3A. Herein, a “structure with reduced randomness” means a structure which is adjusted so that no blocks of the same kind successively appear a predetermined number of times or more along one direction, rather than a completely random structure. For instance, structures such as Random A in FIG. 4(b) and Random B in FIG. 4(c) are examples thereof.

Such controlling of large blocks can also be checked by applying a Fourier transform to a pattern. Herein, to “apply a Fourier transform to a pattern” is directed to a Fourier transform where the heights of fiat portions of the dents and bumps relative to a reference plane are expressed as a two-dimensional function of coordinates x, y within the plane of the light-extraction layer 2007. FIG. 5 is a diagram showing amplitude of spatial frequency components when applying a Fourier transform to patterns. FIG. 5(a) shows results for a pattern with reduced randomness so that no three or more block of the same kind are successively present along the arrangement directions; and FIG. 5(b) shows results for a completely random pattern (in which the dents and the bumps appear with a probability of ½each). The center of the distribution diagram on the right-hand side of FIG. 5 represents a component of zero spatial frequency (DC component). This diagram is illustrated so that spatial frequency increases from the center toward the outside. As will be understood from this figure, in the spatial frequency of a restricted random pattern shown in FIG. 5(a), low-frequency components are suppressed relative to the random pattern shown in FIG. 5(b). In particular, among the spatial frequency components, those components which, are smaller than 1/(2 w) are suppressed.

In the present specification, completely random patterns in which equal numbers of dents and bumps are randomly arrayed and patterns which are adjusted so that no predetermined number of structures or more of the same kind (dents or bumps) are successively present along the arrangement directions may be collectively referred to as “pattern with randomness” or “random pattern”. It is not necessary that plurality of dents and the plurality of bumps are equal in numbers; their numbers may be different.

FIG. 6 is a diagram for explaining an average period in each of a pattern (a) in which two kinds of unit structures (blocks) with a width w are randomly arranged and a pattern (b) in which they are periodically arranged. In the random structure shown in FIG. 6(a), the average period along its arrangement directions is 4 w. On the other hand, in the periodic structure shown in FIG. 6(b), the average period along its arrangement directions is 2 w. Note that an average period w in the case where blocks are randomly arranged can be determined through calculations that are indicated in a balloon in FIG. 6. In other words, in the random structure shown in FIG. 6(a), the probability that dents or bumps of the width w exist is 1/2, while the probability that successive dents or bumps of the width 2 w exist is (1/2)². When this is generalized, along each of the x direction and the y direction, the probability that successive dents or bumps of the width nw (where n is an arbitrary natural number) exist is (1/2)ⁿ. Therefore, an average length wₑₓₚ of structures of the same kind (dents or bumps) in the random bump-dent structure, along the x direction and the y direction, is determined to be 2 w through the following calculation.

$$\begin{matrix}[ math . 1 ] & \\ {w}_{exp} = w \cdot {( \frac{1}{2} )}^{1} + 2 w \cdot {( \frac{1}{2} )}^{2} + 3 w \cdot {( \frac{1}{2} )}^{3} + … = {\sum }_{n = 1}^{∞} nw \cdot {( \frac{1}{2} )}^{n} = 2 w & ( 1 )\end{matrix}$$

The average period, which is a sum of an average length of dents and an average length of bumps, is 4 w.

In a structure with reduced randomness as shown in FIGS. 4(b) and (c), too, an average period can be determined based on a similar principle to the above. A method of determining an average period from the pattern of a structure is shown in FIG. 7. Ellipses (including perfect circles) will now be considered, each being inscribed in a region consisting of successive unit structures of the same kind, with respect to both of the lateral direction and the vertical direction in FIG. 7. In the lower diagram of FIG. 7, an average value of the sizes of the white portions can be determined by calculating an average value of the axial lengths of ellipses which are inscribed in the white portions. The same also applies to the black portions. An average period is defined by a value obtained by taking a sum of these average values. Herein, an “axial length” refers to the length a of the minor axis or the length b of the major axis as illustrated in the upper diagram of FIG. 7.

Light is not diffracted by any structure that is sufficiently smaller than its wavelength. Therefore, regardless of a random structure or a periodic structure, it will not be effective to array unit structures that are 400 nm or less. In other words, given, an average wavelength λ of light occurring from the emission layer 2002, w may be set to 0.73λ (=λ×400/550) or more, for example. As used herein, an average wavelength is defined so that, in the emission spectrum, a sum of intensities of light of any wavelengths greater than the average wavelength is equal to a sum of intensities of light, of any wavelengths smaller than the average wavelength. On the other hand, it has been found through the inventors calculation that, in the case where unit structures are sufficiently larger than the wavelength, a light extraction efficiency of 69% or more can be obtained by setting to 4 in or less for a random structure, of setting w to 4 μm or less for a periodic structure. Since a random structure has an average period of 4 w and a periodic structure has an average period of 2 w, it will be understood that the light extraction efficiency is governed by the average pitch (period), irrespective of the pattern of the structure. The average period, p, may be set to 8 μm or less, for example. Moreover, from the principle of light diffraction, a diffraction pattern of light is determined by a ratio between the structure size (period) and the light wavelength (i.e., p/λ); therefore, the average period p may be set to 14.5(=8/0.55)λ or less, for example.

There is not much difference in light extraction efficiency between a random structure and a periodic structure. However, it is considered that a periodic structure will have large wavelength dependence due to the nature of a diffraction grating, thus resulting in a large color unevenness with respect to the viewing angle. Therefore, in order to reduce color unevenness with respect to the viewing angle, features composed of randomly arrayed structures may be adopted as the bump-dent features.

In embodiments of the present disclosure, after adjustment of the shape parameters of the bump-dent structure (at least one of the height and the period of the bump-dent features) as determined above, they are arranged in accordance with the emission unevenness, as shown in FIG. 2C, for example. Since the luminance of light exiting each subsection on the emission plane is determined by a multiplication of the luminance of the light exiting the light-emitting element and the light extraction efficiency, emission unevenness can consequentially be reduced.

Embodiments which have been conceived by the inventors of the present application according to the above studies are described below.

### Embodiment 1

First, an illuminator (organic EL panel) according to a first embodiment will be described. In the present embodiment, a construction is adopted in which a height distribution is introduced for the bump-dent structure of the light-extraction layer 2007. By varying the height of the bump-dent structure, light extraction efficiency is varied, whereby emission unevenness can be reduced.

<Structure of Organic EL Panel>

FIG. 8 is a diagram showing the structure of an organic EL panel according to the present embodiment. FIG. 8(a) is a plan view of the organic EL panel as viewed from a direction which is perpendicular to the emission plane; FIG. 8(b) is a cross-sectional view taken along line A-A′ in FIG. 8(a); and FIG. 8(c) is a schematic cross-sectional view of the light-extraction layer 2007. In FIG. 8, constituent elements which are identical or similar to those in FIG. 1 are denoted by the same reference numerals. Hereinafter, description of any matter that finds its counterpart in FIG. 1 will be omitted.

As shown in FIG. 8(c), in the light-extraction layer 2007 according to the present embodiment, the bump-dent features differ in height depending on their planar positions. The plane of the light-extraction layer 2007 is divided into a plurality of rectangular regions of a width t, and the heights of the dents and bumps are set so that a desired light extraction efficiency is attained in each region. One region includes plural dents and plural bumps, which are all equal in height. The length of one side of the emission plane of the organic EL panel is e.g. several dozen mm to several hundred mm, and the width t may be set to e.g. several μm to several dozen μm. Each region may include ten or more periods of bump-dent structure along one direction. However, these conditions are not limitative.

<Height Dependence of Light Extraction Efficiency>

First, dependence of light extraction efficiency on the heights of the dents and bumps will be described.

FIGS. 9(a) to (c) are graphs showing dependence of light extraction efficiency on the height h of the bump-dent features in the cases where the bump-dent structure of the light-extraction layer 2007 is composed of the respective patterns of: the diffraction grating shown in FIG. 4(a); Random A shown in FIG. 4(b); and Random E shown in FIG. 4(c). In each graph, the horizontal axis represents the height h (μm) of the bump-dent structure, and the vertical axis represents light extraction efficiency difference ΔE (arbitrary unit). Herein, light extraction efficiency difference ΔE means a light extraction efficiency of the case where the largest light extraction efficiency within the range of calculation is translated to 1, and the smallest light extraction efficiency is translated to 0. The light extraction efficiency difference ΔE is expressed by equation (2) below.

$$\begin{matrix}[ math . 2 ] & \\ Δ E = \frac{{E}_{i} - {E}_{n}}{{E}_{1} - {E}_{n}} & ( 2 )\end{matrix}$$

Herein, E1 denotes the largest extraction efficiency within the range; En denotes the smallest extraction efficiency within the range; and Ei denotes an arbitrary extraction efficiency.

As the change in light extraction efficiency difference relative to the change in height becomes gentler, it becomes easier to reduce emission unevenness through height adjustments. From the results of FIG. 9, the change in light extraction efficiency difference relative to height is gentler in (c) Random B than in (b) Random A than in (a) diffraction grating; thus, their effectivenesses for emission unevenness reduction are in this descending order.

In this calculation, the pitch (average period) p of the bump-dent structure is 0.6 μm in Random A, and 1.8 μm in the diffraction grating and Random B. The transparent substrate 2000 has a refractive index of 1.5; the low-refractive index layer 2008 has a refractive index of 1.45; and the high-refractive index layer 2009 has a refractive index of 1.76.

As shown in FIG. 9(a), in the case where the diffraction grating is adopted, the light extraction efficiency difference ΔE can be varied from 0 to 1, within a range of structure height h from 0.4 to 2 μm. As shown in FIG. 9(b), in the case of adopting a random structure with rectangular fundamental shapes (Random A), h may be set within a range from 0.4 to 1.2 μm. In the case of adopting a random structure with hexagonal fundamental shapes (Random B), h may be set within a range from 0.4 to 1.2 μm.

<Method for Suppressing Emission Unevenness>

Next, with reference to FIGS. 10A to 10D, a method for suppressing emission unevenness according to the present embodiment will be described. FIG. 10A is a diagram showing a luminance distribution on an emission plane with emission unevenness, based on light from a light source (emission layer 2002) ; FIG. 10B is a diagram showing a light extraction efficiency distribution of the light-extraction layer 2007 according to the present embodiment; FIG. 10C is a diagram showing a height distribution of the bump-dent structure for attaining the above light extraction efficiency distribution; and FIG. 10D is a diagram showing an exemplary luminance distribution on the emission plane which is finally obtained from the illuminator when a light-extraction layer 2007 having the light extraction efficiency distribution of FIG. 10B and the height distribution of FIG. 10C is applied to the luminance distribution of FIG. 10A. As shown in the figure, in the present embodiment, the emission plane is divided into a plurality of rectangular regions of a width t along the arrangement directions, and based on the luminance of each region, the light extraction efficiency difference and the heights of the dents and bumps in each region are determined. Herein, a case is envisaged where emission unevenness is to be suppressed by adjusting the heights of the dents and bumps according to the Random B pattern with a pitch of 1.8 μm as shown in FIG. 4(c) and FIG. 9(c).

FIG. 10A shows an exemplary luminance distribution on the emission plane. The value in each region represents a luminance of the case where the highest luminance is translated to 1 and the lowest luminance is translated to 0. Note that brightness or darkness on the panel is indicated by different tones which correspond to luminance. It can be seen that noticeable emission unevenness exists in the luminance distribution shown in FIG. 10A.

In order to suppress the emission unevenness depicted in FIG. 10A, first, a light extraction efficiency difference ΔE is set based on the emission amount in each region. Herein, as shown in FIG. 10B, it is set so that ΔE=0 holds in places associated with the maximum luminance in FIG. 10A and that ΔE=1 holds in places associated with the lowest luminance. The value of each region in FIG. 10B indicates the aforementioned light extraction efficiency difference ΔE. Places with greater values of light extraction efficiency difference ΔE enjoy improved luminance when the light-extraction layer 2007 is provided.

Next, based on FIG. 9(c) and FIG. 10B, heights of the bump-dent structure are set. FIG. 10C shows a height distribution of the bump-dent structure as set in this manner. In FIG. 10C, the value in each region represents the height of the bump-dent structure in that place (in units of μm). In the present embodiment, when the structure height is to be varied between two adjacent regions, a difference of 100 nm or more is enforced between their heights in order to account for processing accuracy; however, such limitation may not be enforced.

FIG. 10D shows a luminance distribution in the case where, given the unevenness in luminance as illustrated in FIG. 10A, a bump-dent structure having the height distribution of FIG. 10C is introduced. Let the luminance in each region of FIG. 10A be Li and the luminance in each region of FIG. 10D be Li′, then, Li′ is expressed as Li′=(ΔE+1) Li. As compared to the luminance distribution shown in FIG. 10A, it can be seen that emission unevenness is suppressed in the luminance distribution shown in FIG. 10D.

Next, with reference to FIG. 10A and FIG. 11A to FIG. 11C, an exemplary method of deriving the luminance and emission efficiency for each region will be described FIG. 11A to FIG. 11C show steps of calculation up until the light extraction efficiency distribution shown in FIG. 10B is obtained. In these figures, the values in the periphery of the emission plane are to be used in a below-described step of calculating the light extraction efficiency, where 0 denotes a value for the anode and 1 denotes a value for the cathode. FIG. 11A and FIG. 11B represent midway states of calculation, whereas FIG. 11C shows completion of the calculation, resulting in an extraction efficiency distribution shown in FIG. 10B. Herein, for convenience of explanation, any value representing the luminance or light extraction efficiency in each region of FIGS. 10A and 10B is denoted as coordinates in the right direction and the lower direction of an origin which is defined at the upper left end of each diagram. Specifically, in a region denoted by coordinates (X, Y), its luminance is expressed as L (X, Y) and its extraction efficiency expressed as b (X, Y). For example, in FIG. 10A, there is a luminance value of 0.66 at three points to the right and four points down from the origin; this will be expressed as L (3, 4)=0.66. Hereinafter, based on this expression, a method of deriving the light extraction efficiency in each region of FIG. 10B will be described.

(1) First, the luminance in each region of the emission plane in a construction which lacks the light-extraction layer 2007 is measured; and from the resultant luminance distribution, a maximum luminance and a minimum luminance are determined. The luminance in each region may be measured by any arbitrary measurement device.

(2) Next, from the resultant maximum luminance, each region's ratio to the maximum luminance (i.e., luminance in each region/maximum luminance) is determined. This produces the luminance distribution shown in FIG. 10A.

(3) Then, in order to calculate the light extraction efficiency in each region, first, the extraction efficiency in the regions of lowest luminance (corresponding to the light extraction efficiency difference shown in FIG. 9) is set to 1, and the extraction efficiency in the regions of highest luminance is set to 0. This produces the distribution shown in FIG. 11A.

(4) Next, the extraction efficiency in each region is calculated from an average value of the extraction efficiencies in the four upper/lower/right/left neighboring regions. Specifically, the extraction efficiency b (X, Y) in a region that is denoted by coordinates (X, Y) is determined by calculating an average value of b (X−1, Y), b (X+1, Y), b (X, Y−1), and b (X, Y+1). In this calculation, extraction efficiencies at edges of the emission plane, where there exist only three or fewer upper/lower/right/left neighboring regions, are assumed to be 0 for the anode and 1 for the cathode. FIG. 11B shows a certain midway state in this calculation. In this state, the values of the regions are not finalized yet; if the value of a given region changes, the values of its neighboring regions may also change.

(5) Calculation is performed for each region according to the method of (4) above, and the calculation is supposed to be complete when extraction efficiencies for all regions have been calculated. This produces the extraction efficiency distribution shown in FIG. 11C.

Once the extraction efficiency distribution is determined, a bump-dent structure pattern for the light-extraction layer may be arbitrarily decided, and the heights of the dents and bumps in each region according to that pattern may be calculated from the correspondence indicated in FIG. 9, whereby a height distribution as shown in FIG. 10C can be obtained. Note that, without being limited to the above methods, any methods may be used for calculating the light extraction efficiency and height distribution of the dents and bumps. According to the present embodiment, there is no need to provide auxiliary electrodes, whereby thickness can be suppressed all across the panel. By varying the height of the bump-dent structure in accordance with the emission amount, the emission unevenness of the illuminator can be suppressed without using auxiliary electrodes.

<Details of Constituent Elements>

Next, the respective constituent elements will be described in detail.

The metal electrode 2003 is an electrode (cathode) for injecting electrons into the emission layer 2002. When a predetermined voltage is applied between the metal electrode 2003 and the transparent electrode 2001 by the feed portion 2006, electrons are injected from the metal electrode 2003 into the emission layer 2002. As the material of the metal electrode 2003, for example, silver (Ag), aluminum (Al), copper (Cu), magnesium (Mg), lithium (Li), sodium (Na), or an alloy containing these as main components, etc., can be used. Moreover, a combination of such metals may be stacked to form the metal electrode 2003; and a transparent electrically-conductive material such as indium tin oxide (ITO) or PEDOT:PSS (a mixture of polythiophene and polystyrene sulfonate) may be stacked in contact with such metals to form the metal electrode 2003.

The transparent electrode 2001 is an electrode (anode) for injecting holes into the emission layer 2002. The transparent electrode 2001 may be composed of a material such as a metal, an alloy, or an electrically-conductive compound having a relatively large work function, a mixture thereof, etc. Examples of the material of the transparent electrode 2001 include: inorganic compounds such as ITO, tin oxides, zinc oxides, IZO (registered trademark), and copper iodide; electrically conductive polymers such as PEDOT and polyaniline; electrically conductive polymers doped with an arbitrary acceptor the like; electrically-conductive light transmitting-materials such as carbon nanotubes.

After forming the light-extraction layer 2007 on the transparent substrate 2000, the transparent electrode 2001 can be formed as a thin film by a sputtering technique, a vapor deposition technique, an application technique, or the like. The sheet resistance of the transparent electrode 2001 is set to e.g. several hundred Ω/□ or less, and in some instances may be set to 100 Ω/□ or less. The film thickness of the transparent electrode 2001 is e.g. 500 nm or less, and in some instances may be set in a range of 10 to 200 nm. As the transparent electrode 2001 becomes thinner, the light transmittance will improve, but the sheet resistance will increase because sheet resistance increases in inverse proportion to film thickness. When organic EL is to be achieved in a large area, this may lead to high voltage issues, and problems of nonuniform luminance due to nonuniform current density caused by a voltage drop. In order to avoid this trade off, auxiliary wiring (grid) of a metal or the like may be formed on the transparent electrode 2001. As the material of the auxiliary wiring, those with good electrically conductive are used. For example, Ag, Cu, Au, Al, Rh, Ru, Ni, Mo, Cr, Pd, or an alloy thereof (MoAlMo, AlMo, AgPdCu, etc.) can be used. At this time, the grid portion may be subjected to an insulation treatment to prevent a current flow, so that the metal grid will not serve as a light-shielding material. In order to prevent diffused light from being absorbed by the grid, a metal with high reflectance may be used for the grid.

Although the present embodiment illustrates that the transparent electrode 2001 is an anode and the metal electrode 2003 is a cathode, the polarities of these electrodes may be opposite. Materials similar to those mentioned above can be used for the transparent electrode 2001 and the metal electrode 2003 even in the case where the transparent electrode 2001 is the cathode and the metal electrode 2003 is the anode.

The emission layer 2002 is made of a material which generates light through recombination of electrons and holes that are injected from the transparent electrode 2001 and the metal electrode 2003. For example, the emission layer 2002 can be made of a low-molecular-weight or high-molecular-weight light-emitting material, or any commonly-known light-emitting material such as metal complexes. Although not shown in FIG. 8, an electron transport layer and a hole transport layer may be provided on both sides of the emission layer 2002. The electron transport layer is provided on the metal electrode 2003 (cathode) side, while the hole transport layer is provided on the transparent electrode 2001 (anode) side. In the case where the metal electrode 2003 is the anode, the electron transport layer is to be provided on the transparent electrode 2001 side, and the hole transport layer is to be provided on the metal electrode 2003 side.

The electron transport layer can be selected as appropriate from among compounds having an electron-transporting property. Examples of such compounds include: Alq3 or other metal complexes known as electron-transporting materials; compounds having heterocycles, such as phenanthroline derivatives, pyridine derivatives, tetrazine derivatives, and oxadiazole derivatives; and the like. However, without being limited to these materials, any commonly-known electron-transporting material can be used. The hole transport layer can be selected as appropriate from among compounds having hole-transporting property. Examples of such compounds include 4,4′-bis[N-(naphthyl)-N-phenyl-amino]biphenyl (α-NPD); N,Nα-bis (3-methylbiphenl)-(1,1′-biphenyl)-4,4′-diamine (TPD); 2-TNATA; 4,4′,4″-tris(N-(3-methphenyl) N-phenylamino) triphenylamine (MTDATA); 4,4′-N,N′-dicarbazolebiphenyl (CBP); spiro-NPD; spiro-TPD; spiro-TAD; or, triarylamine-type compounds such as TNB, amine compounds containing carbazole group, amine compounds including fluorene derivatives, and so on. However, without being limited to these materials, any commonly-known hole-transporting material can be used. Thus, in addition to the emission layer 2002, other layers such as an electron transport layer and a hole transport layer may be provided between the metal electrode 2003 and the transparent electrode 2001. In the present specification, the layer(s) between the metal electrode 2003 and the transparent electrode 2001 may collectively be referred to as an “organic EL layer”.

Without being limited to the above examples, various structures may be adopted as the structure of the organic EL layer. For example, a multilayer structure of a hole transport layer and the emission layer 2002, or a multilayer structure of the emission layer 2002 and an electron transport layer may be adopted. Moreover, a hole injection layer may be present between the anode and a hole transport layer, or an electron injection layer may be present between the cathode and an electron transport layer. Without being limited to a single layer structure, the emission layer 2002 may have a multilayer structure. For example, when the desired emission color is white, the emission layer 2002 may be doped with three dopant dyes of red, green, and blue. Moreover, a multilayer structure of a blue hole-transporting emission layer, a green electron-transporting emission layer, and a red electron-transporting emission layer may be adopted; or a multilayer structure of a blue electron-transporting emission layer, a green electron-transporting emission layer, and a red electron-transporting emission layer may be adopted. Furthermore, a structure in which a plurality of emission units are stacked via an intermediate layer having a light transmitting property and electrically conductivity (i.e., a multiunit structure in electrical series connection) may be adopted, where each emission unit is defined as layers including an element that emits light when interposed between an anode and a cathode and a voltage is applied thereto.

The transparent substrate 2000 is a member for supporting the light-extraction layer 2007, the transparent electrode 2001, the emission layer 2002, and the metal electrode 2003. As the material of the transparent substrate 2000, for example, a transparent material such as glass or resin can be used. The transparent substrate 2000 has a refractive index on the order of 1.45 to 1.65, for example; however, a high-refractive index substrate having a refractive index of 1.65 or more or a low-refractive index substrate having a refractive index less than 1.45 may also be used.

The light-extraction layer 2007 is a light-transmitting layer which is provided between the transparent substrate 2000 and the transparent electrode 2001. The light-extraction layer 2007 includes the low-refractive index layer 2008 formed on the transparent substrate 2000 side and the high-refractive index layer 2009 formed on the transparent electrode 2001 side. Their interface include bump-dent features as mentioned earlier.

A portion of the light occurring from the emission layer 2002 is incident, on the light-extraction layer 2007 via the transparent electrode 2001. At this time, any light that strikes at an incident angle exceeding the critical angle, which would normally have undergone total reflection, receives a diffractive action by the light-extraction layer 2007 so that a portion thereof is extracted through the transparent substrate 2000. The light which has not been extracted by the light-extraction layer 2007 is reflected so as to travel at a different angle toward the emission layer 2002, but is thereafter reflected by the metal electrode 2003, thus again being incident on the light-extraction layer 2007. On the other hand, a portion of the light occurring from the emission layer 2002 is reflected by the electrode 11, and then is transmitted through the transparent electrode 2001 so as to be incident on the light-extraction layer 2007. Thus, providing the light-extraction layer 2007 allows light to be extracted toward the exterior through repetitive multiple reflection.

The bump-dent structure at the boundary between the low-refractive index layer 2008 and the high-refractive index layer 2009 can be formed by, for example, forming bump-dent features on the low-refractive index layer 2008, and thereafter filling up the dents and bumps with the high-refractive index material. When subsequently forming the transparent electrode 2001, the emission layer 2002, and the metal electrode 2003, short-circuiting is likely to occur between the transparent electrode 2001 and the metal electrode 2003 if the surface of the high-refractive index layer 2009 has poor planarity. In that case, the device may not be capable of being lit, thus resulting in a poor production yield during manufacture. Thus, in the present embodiment, a construction is adopted which can minimize the height of the bump-dent features, thus to ensure planarity after filling with the high-refractive index layer 2009. Moreover, lowering the height of the bump-dent structure in this manner also makes it possible to reduce the amounts of materials used of the low-refractive index layer 2008 and the high-refractive index layer 2009, thus providing for low cost.

On the other hand, from the standpoint, of improving the light, extraction efficiency, the height (size) of the bump-dent structure needs to be at least, on the order of ¼ times the wavelength of light. This will ensure sufficient optical phase differences for diffracting light, whereby the light extraction efficiency can be improved. From the above standpoints, in the present embodiment, a diffraction element with a random structure or a periodic structure, etc., having a height (size) around 1 μm, is adopted as an exemplary bump-dent structure.

Light which has traveled through the bump-dent structure is incident on the low-refractive index layer 2008. If the thickness of the low-refractive index layer 2008 is ½ or less of the wavelength of light, light will not propagate through the low-refractive index layer 2008, but will be transmitted through the transparent substrate 2000 via an evanescent field, so that the effect of deflecting light toward the lower angles with the low-refractive index layer 2008 is no longer expectable. Thus, the thickness of the low-refractive index layer 2008 according to the present embodiment may be set to ½ times or more of the average wavelength.

The refractive index of the high-refractive index layer 2009 may be set to e.g. 1.73 or more. The material for the high-refractive index layer 2009 may be, for example: an inorganic material with a relatively high refractive index, e.g., ITO (indium tin oxide), TiO₂ (titanium oxide), SiN (silicon nitride), Ta₂O₅ (tantalum pentoxide), or ZrO₂ (zirconia); a high-refractive index resin; or the like.

It is commonplace to use glass or resin as the transparent substrate 2000, which have refractive indices on the order of 1.5 to 1.65. Therefore, as the material of the low-refractive index layer 2008, inorganic materials, e.g., glass and SiO₂ (quartz), or resins can be used.

<Method of Producing an Organic EL Panel>

Next, an exemplary method of producing an organic EL panel according to the present embodiment will be described.

FIG. 12 shows an exemplary method of producing an organic EL panel. As described earlier, the light-extraction layer 2007 is composed of a low-refractive index layer (resin) 2008 forming a light extraction structure and a high-refractive index layer (resin) 2009 in which the low refractive index layer 2008 is buried. The height of the bump-dent structure of the low-refractive index layer 2008 is constant within the same region of width t; when height varies between two adjacent regions, the difference between their heights may be set to 100 nm or more. Such a bump-dent structure can be produced by nanoimprint technique, using a mold having formed thereon a plurality of bump-dent features in each of a plurality of square regions of width t, the bump-dent features being equal in height, for example.

As shown in FIG. 12(a), first, a transparent substrate 2000 is provided. With a nanoimprint technique using the aforementioned mold, as shown in FIG. 12(b), a light-extraction layer 2007 having bump-dent features at the interface between the low-refractive index layer 2008 and the high-refractive index layer 2009 is formed on the transparent substrate 2000. Next, as shown in FIG. 12(c), a transparent electrode 2000 composed of a material such as ITO is formed. A portion 400 of the transparent electrode 2000 is removed to form a feed portion 2006. On the transparent electrode 2001 having been thus patterned, an organic EL layer containing an emission layer 2002 is formed as shown in FIG. 12(d). The organic EL layer is formed so as to partially overlap the removed portion 400 of the transparent electrode 2001. This prevents short-circuiting between the transparent electrode 2001 and a metal electrode 2003 to be formed thereon. As shown in FIG. 12(e), the metal electrode 2003 is formed, a sealant 2005 of UV-curing nature is applied so as to surround the organic EL layer. Then, as shown in FIG. 12(f), after the metal electrode 2003 and the feed portion 2006 are connected, a sealing glass is attached and fixed in place. An organic EL panel can be produced by this method.

The imprinting mold for use in the aforementioned nanoimprint technique can be produced by e.g. a step-and-repeat technique, such that regions of width t, each containing a plurality of dents and bumps of the same height but the height of such dents and bumps being varied from region to region, are repetitively formed across a large area. Herein, the width t of a region of the same structure height is set based on results of calculating a dependence of light extraction efficiency on width t as shown in FIG. 13, for example. In the example shown in FIG. 13, for instance, it may be set to 10 μm or more so that the rate of change in light extraction efficiency relative to the width t falls within 1%.

Moreover, by using a semiconductor process or cutting, bump-dent features may be formed through direct processing of a material. In that case, the light diffusing layer 2007 is composed of bump-dent features which have been processed on the substrate 2000. In this case, the substrate 2000 and the low-refractive index layer 2008 are made of the same material. A semiconductor process would be effective in carrying out a fine pattern fabrication to control the pattern on the order of microns. Use of a semiconductor process allows to process a step structure with flat faces (i.e., having discrete height levels). For example, a structure with two height levels can be processed through a single etching. A structure with three or four height levels can be processed through two etching processes.

Note that the method for determining the height distribution is not limited to the above method. Any method can be used that allows the height of the dents and bumps in the light extraction structure to be varied. Moreover, a height distribution based on there being plural subsections as shown in FIG. 10C is not a requirement. Rather, any height distribution may be provided that achieves at least some reduction in emission unevenness.

An organic EL panel is known to suffer from total reflection also because of a refractive index difference between the surface of the transparent substrate 2000 and air. Therefore, a diffraction sheet having a light extraction structure, e.g., a diffraction grating or nanostructure, may be provided on the surface of the transparent substrate 2000. The light extraction efficiency can be further improved by providing such a diffraction sheet.

### Embodiment 2

Next, an illuminator (organic EL panel) according to a second embodiment will be described. The present embodiment differs from Embodiment 1 in that the period (pitch) of the dents and bumps is varied, rather than varying the height of the dents and bumps. Varying the pitch of the dents and bumps is also able to alter the light extraction efficiency, thus being effective for emission unevenness suppression. Hereinafter, differences from Embodiment 1 will mainly be described, and description of any overlapping matters will be omitted.

<Structure of Organic EL Panel>

FIG. 14 is a diagram showing the organic EL panel of an structure according to the present embodiment. FIG. 14(a) is a plan view of the organic EL panel as viewed from a direction which is perpendicular to the emission plane; FIG. 14(b) is a cross-sectional view taken along line A,-A′ in FIG. 14(a); and FIG. 14(c) is a schematic cross-sectional view of the light-extraction layer 2007. In FIG. 14, constituent elements which are identical or similar to those in FIG. 8 are denoted by the same reference numerals.

As shown in FIG. 14(c), in the light-extraction layer 2007 according to the present embodiment, the bump-dent features differ in pitch depending on their planar positions. The plane of the light-extraction layer 2007 is divided into a plurality of rectangular regions of a width t, and the pitch of the bump-dent structure is set so that a desired light extraction efficiency is attained in each region. One region includes plural dents and plural bumps, which are all equal in pitch.

<Period (Pitch) Dependence of Light Extraction Efficiency>

First, dependence of light extraction efficiency on the pitch of the dents and bumps will be described.

FIGS. 15(a) to (c) are graphs showing dependence of light extraction efficiency on the pitch p of the bump-dent features in the cases where the bump-dent structure of the light-extraction layer 2007 is composed of the respective patterns of: the diffraction grating shown in FIG. 4(a); Random shown in FIG. 4(b); and Random B shown in FIG. 4(c). Herein, the structure height is 0.6 μm. Similarly to the conditions of calculation in FIG. 9, the transparent substrate 2000 has a refractive index of 1.5, the low-refractive index layer 2008 has a refractive index of 1.45, and the high-refractive index layer 2009 has a refractive index of 1.76. In each graph, the horizontal axis represents the pitch p (μm) of the bump-dent structure, and the vertical axis represents light extraction efficiency difference ΔE (arbitrary unit). Tight extraction efficiency difference ΔE is, as has been described in Embodiment 1, a light extraction efficiency of the case where the largest light extraction efficiency within the range of calculation is translated to 1 and the smallest light extraction efficiency is translated to 0. The light extraction efficiency difference ΔE is expressed by equation (2) above.

As the change in light extraction efficiency difference relative to the change in pitch becomes gentler, it becomes easier to reduce emission unevenness through height adjustments. From the results of FIG. 15, the change in light extraction efficiency difference relative to height is gentler in (c) Random B than in (a) diffraction grating than in (b) Random A; thus, their effectivenesses for emission unevenness reduction are in this descending order.

As shown in FIG. 15(a), in the case where the diffraction grating is adopted, the light extraction efficiency difference ΔE can be varied from 0 to 1, within a range of pitch p from 0.6 to 3 μm. As shown in FIG. 15(b), in the case of adopting a random structure with square fundamental shapes (Random A), p may be set within a range from 5.4 to 1.8 μm. In the case of adopting a random structure with hexagonal fundamental shapes (Random B), p may be set within a range from 0.4 to 2.4 μm.

<Method for Suppressing Emission Unevenness>

Next, with reference to FIGS. 16A to 16D, a method for suppressing emission unevenness according to the present embodiment will be described. As shown in the figure, in the present embodiment, the emission plane is divided into a plurality of rectangular regions of a width t along the arrangement directions, the light, extraction efficiency difference and the pitch of the dents and bumps in each region are determined. As used herein, the “pitch” refers to the aforementioned “average period”, which is subject to different calculation methods depending on the bump-dent structure pattern. Herein, a case is envisaged where emission unevenness is to be suppressed by adjusting the pitch of the dents and humps according to the Random B pattern with a height of 0.6 μm as shown in FIG. 4(c) and FIG. 14(c).

FIG. 16A shows an exemplary luminance distribution on the emission plane. The value in each region represents a luminance of the case where the highest luminance is translated to 1 and the lowest luminance is translated to 0. Note that brightness or darkness on the panel is indicated by different tones which correspond to luminance. It can be seen that noticeable emission unevenness exists in the luminance distribution shown in FIG. 16A.

In order to suppress the emission unevenness depicted in FIG. 16A, first, a light extraction efficiency difference ΔE is set based on the emission amount in each region. Herein, as shown in FIG. 16B, ills set so that ΔE-0 holds in places associated with the maximum luminance in FIG. 16A and that ΔE=1 holds in places associated with the lowest luminance. The value of each region in FIG. 16B indicates the light extraction efficiency difference ΔE. Places with greater values of light extraction efficiency difference ΔE enjoy improved luminance when the light-extraction layer 2007 is provided.

Next, based on FIG. 15(c) and FIG. 16B, pitches of the bump-dent structure are set. FIG. 16C shows a pitch distribution of the bump-dent structure as set in this manner. In FIG. 16C, the value in each region represents the pitch of the bump-dent structure in that place. In the present embodiment, when the pitch is to be varied between two adjacent regions, a difference of 100 nm or more is enforced between their pitches in order to account for processing accuracy; however, such limitation may not be enforced.

FIG. 16D shows a luminance distribution in the case where, given the unevenness in luminance as illustrated in FIG. 16A, a bump-dent structure having the pitch distribution of FIG. 16C is introduced. Let the luminance of each region of FIG. 16A be Li, and the luminance of each region of FIG. 16D be Li′, then, Li′ is expressed as Li′=(ΔE+1) Li. As compared to the luminance distribution shown in FIG. 16A, it can be seen that emission unevenness is suppressed in the luminance distribution shown in FIG. 16D. The method of deriving the luminance and emission efficiency for each region is identical to that of Embodiment 1, and the description thereof is omitted.

According to the above method, there is no need to provide auxiliary electrodes, whereby thickness can be suppressed all across the panel. According to the present embodiment, By varying the height of the bump-dent structure in accordance with the emission amount, the emission unevenness of the illuminator can be suppressed without using auxiliary electrodes.

The method of producing the organic EL panel of the present embodiment is similar to the method described in Embodiment 1, and the description thereof is omitted. In the present embodiment, too, the width t of each region may be set to 10 μm or more so that the rate of change in light extraction efficiency relative to the width t falls within 1%, as has been described with reference to FIG. 13, for example. In the present embodiment, too, a diffraction sheet having a light extraction structure, e.g., a diffraction grating or nanostructure, may be provided on the surface of the transparent substrate 2000.

### Other Embodiments

Thus, Embodiments 1 and 2 have been described above; however, the present invention not limited to these embodiments. Any implementation that results from applying various modifications that might occur to those skilled in the art to each embodiment, or combining constituent elements from different embodiments is also encompassed within the present disclosure. Other exemplary embodiments are illustrated below.

<Film Sealing>

The description of the above embodiments is directed to a structure in which the organic EL layer is protected from moisture or oxygen by the sealant 2005 made of a transparent substance and the sealing substrate 2004; however, the sealing method is not limited to such a structure. Effects similar to the above can be obtained with any structure that similarly transmits light. For example, as shown in FIG. 17, a construction may be adopted where the organic. EL device is sealed with transparent resin 1101. Adopting such a construction allows the sealing substrate 2004 to be omitted, and simplifies the production steps.

<UV-Curing Resin, Thermosetting Resin>

Although the above embodiments illustrate implementations where a height or pitch distribution of the bump-dent structure of the light-extraction layer 2007 is created by using an imprinting mold, such implementations are riot limitative. For example, a resin of UV-curing nature may be used. In that case, level differences in the bump-dent structure can be created by adjusting the amount UV exposure. A thermosetting resin may also be used, in which case level differences can be created by adjusting the heating temperature. Furthermore, the position of the light-extraction layer 2007 is not limited to inside the substrate. Generally speaking, total reflection occurs at the interface between air and the transparent substrate 2000 being made of glass or the like. In order to suppress this total reflection, the organic EL panel may include a light extraction sheet on which a light extraction structure having bump-dent features is formed from a UV-curing resin or a thermosetting resin.

<Narrow Frame>

The above embodiments are directed to implementations in which the height or pitch distribution of the bump-dent structure is determined in accordance with a voltage drop distribution (or emission intensity distribution) in the panel; however, such implementations are not limitative. For example, in order to account for emission unevenness due to light propagating within the substrate from the emission plane, a light extraction structure similar to the light-extraction layer 2007 may be provided at an edge of the substrate to thereby suppress emission unevenness.

In general, voltage drop would appear particularly noticeably in the central portion of the panel, and thus the central portion is likely to have reduced luminance. Therefore, a construction may be adopted which lowers the light extraction efficiency at the periphery of the panel so as to allow the light which would otherwise have been extracted to propagate to the panel central portion. Such a construction will allow for efficient utilization of light exiting the organic EL panel.

Although the above description is mainly directed to a plane emission device in which an organic EL device is used, the light-emitting element is not limited to an organic EL device. For example, an illuminator which utilizes an inorganic light-emitting element is also applicable to the light extraction structures according to the above embodiments.

### INDUSTRIAL APPLICABILITY

An illuminator according to an embodiment of the present disclosure can be used as surface lighting whose emission unevenness reduced. For example, it is applicable to flat panel displays, backlights for liquid crystal display devices, light sources for illumination, and the like. The illuminator is not limited to a monochromatic light source, but is also applicable to a white illuminator.

### REFERENCE SIGNS LIST

300 connecting portion

500 dent

600 bump

2000 transparent substrate

2001 3transparent electrode

2002 organic layer

2003 metal electrode

2004 glass substrate

2005 sealant

2006 feed portion

2007 light-extraction layer

2008 resin (low-refractive index layer)

2009 resin (high-refractive index layer)

1. An illuminator comprising:
a light-emitting element; and
a light-extraction layer which transmits light occurring from the light-emitting element,
the light-emitting element including
a first electrode layer on the light-extraction layer side, the first electrode layer having a light transmitting property,
a second electrode layer on an opposite side from the light-extraction layer,
an emission layer between the first and second electrode layers, and
a feed portion connected to at least one of the first electrode layer and the second electrode layer to apply a voltage between the first electrode layer and the second electrode layer, wherein,
the light-extraction layer has a structure in which a low-refractive index layer having a relatively low refractive index and a high-refractive index layer having a higher refractive index than does the low-refractive index layer are stacked, an interface between the low-refractive index layer and the high-refractive index layer representing bump-dent features;
the light-extraction layer includes a first region and a second region which is more distant from the feed portion than is the first region; and
the bump-dent features are adapted so that the second region has a higher light extraction efficiency than does the first region.

2. The illuminator of claim 1, wherein the light-extraction layer is divided into a plurality of regions including the first and second regions, the bump-dent features being adapted so that the light extraction efficiency in each region increases as there is a smaller amount of transmitted light through a portion of the first electrode layer opposing that region.

3. The illuminator of claim 1, wherein an average value of heights of the bump-dent features in the second region is greater than an average value of heights of the bump-dent features in the first region.

4. The illuminator of claim 3, wherein the light-extraction layer is divided into a plurality of regions including the first and second regions such that the bump-dent features in each region has a constant height, and the height of the bump-dent features in each region is determined in accordance with an amount of transmitted light through a portion of the first electrode layer opposing that region.

5. The illuminator of claim 4, wherein the plurality of regions include two regions differing in teens of the height of the bump-dent features, the difference in terms of the height between the two regions being 100 nm or more.

6. The illuminator of claim 1, wherein an average value of periods of the bump-dent features in the second region is longer than an average value of periods of the bump-dent features in the first region.

7. The illuminator of claim 6, wherein the light-extraction layer is divided into a plurality of regions including the first and second regions, and an average value of periods of the bump-dent features in each region is determined in accordance with an amount of transmitted light through a portion of the first electrode layer opposing that region.

8. The illuminator of claim 1, wherein the bump-dent features are shaped so that a plurality of dents and a plurality of bumps are arrayed in a pattern with two-dimensional randomness.

9. The illuminator of claim 1, wherein the bump-dent features are structured so that a plurality of dents and a plurality of bumps are in a periodic two-dimensional array.

10. The illuminator of claim 1, wherein,
the light-extraction layer further includes a light-transmitting substrate;
the low-refractive index layer is formed on a face of the light-transmitting substrate that is closer to the light-emitting element; and
the high-refractive index layer is formed between the low-refractive index layer and the first electrode layer.
